(19) United States
(12) Patent Application Publication
(10) Pub. No.: US 2024/0222214 A1
(43) Pub. Date: Jul. 4, 2024

(54) SINGLE-SIDED COOLING POWER MODULE AND METHOD OF MANUFACTURING THE SAME

(71) Applicant: HYUNDAI MOBIS CO., LTD., Seoul (KR)

(72) Inventors: Yoon Ju KIM, Hwaseong-si (KR); Jeong Kwang SEO, Seongnam-si (KR); Yu Cheol PARK, Anyang-si (KR); Chan Yang CHOE, Seoul (KR)

(73) Assignee: HYUNDAI MOBIS CO., LTD., Seoul (KR)

(21) Appl. No.: 18/503,543

(22) Filed: Nov. 7, 2023

(30) Foreign Application Priority Data
Dec. 29, 2022 (KR) 10-2022-0188608

(51) Int. Cl. H01L 23/31; H01L 23/00; H01L 23/498

(52) U.S. Cl. CPC H01L 23/3121; H01L 23/49811; H01L 23/49844; H01L 24/48; H01L 2224/48155; H01L 2924/181

(57) ABSTRACT

Single-sided cooling power module and methods of manufacturing are disclosed where the cooling power module includes a pattern formed on a direct bonded copper (DBC) substrate to conduct electricity, a power device chip disposed on the DBC substrate and electrically connected to the pattern, a power terminal coupled to the DBC substrate and electrically connected to the pattern, and a signal pin extending in a direction perpendicular to a surface of the DBC substrate and facing the power device chip, the signal pin being electrically connected to the pattern.

### CROSS-REFERENCE TO RELATED APPLICATIONS

This application claims priority under 35 U.S.C. § 119 to Korean Patent Application No. 10-2022-0188608, filed on Dec. 29, 2022, in the Korean Intellectual Property Office, the entire disclosure of which is incorporated herein by reference for all purposes.

### BACKGROUND

### 1. Field

The following disclosure relates to a single-sided cooling power module and a method of manufacturing the same, and more particularly, to a single-sided cooling power module having a small volume with a reduced inductance and a method of manufacturing the same.

### 2. Discussion of Related Art

A power semiconductor includes a power switching device and a control IC, and is a semiconductor that serves to convert, disassemble, and manage power entering an electronic device.

Such a power semiconductor requires higher pressure durability and higher reliability than a general semiconductor, and there has been an increasing demand for power semiconductors due to the development of hybrid vehicles and electric vehicles.

Power modules used in hybrid vehicles and electric vehicles include power semiconductor devices used to convert DC to AC or AC to DC. Power modules are implemented through major technologies for power semiconductor devices and packaging material modules such as integration design technologies, manufacturing process technologies, and characteristic test and reliability evaluation technologies. Power modules need to have high durability and high reliability because they operate in a harsh environment such as a high-temperature environment or a strong-vibration environment.

Meanwhile, a conventional single-sided cooling power module is installed in such a manner that a signal pin faces a power terminal on a direct bonded copper (DBC) substrate.

FIG. 1 is a diagram illustrating a conventional single-sided cooling power module.

Specifically, referring to FIG. 1, the conventional single-sided cooling power module 100 includes a DBC substrate 110, a power terminal 120, a power device chip 130, a signal pin 140, a wire 150, and a molding unit 160, and the signal pin 140 is installed on the DBC substrate 110 in such a manner as to face the power terminal 120 in parallel to one surface of the DBC substrate 110 facing the power device chip 130.

When the signal pin 140 is installed as described above, there are problems in that the power module has a large volume, and the distance between the power device chip 130 and the signal pin 140 is relatively long, which increases an inductance.

Therefore, there is a need to develop a single-sided cooling power module having a small volume with a reduced inductance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided single-sided cooling power module including a pattern formed on a direct bonded copper (DBC) substrate to conduct electricity, a power device chip disposed on the DBC substrate and electrically connected to the pattern, a power terminal coupled to the DBC substrate and electrically connected to the pattern, and a signal pin extending in a direction perpendicular to a surface of the DBC substrate and facing the power device chip, the signal pin being electrically connected to the pattern.

The single-sided cooling power module may include a socket disposed on the surface of the DBC substrate and being electrically connected to the pattern, wherein the signal pin may be coupled to the socket and electrically connected to the socket.

The socket may include a plate portion comprising a bottom surface bonded to the surface of the DBC substrate and an ultrasonically bondable surface, an accommodating portion extending from the plate portion in a direction perpendicular to the surface of the DBC substrate, and an accommodating hole configured to receive the signal pin, the accommodating hole being formed in the accommodating portion.

At least one protrusion may be formed on an inner circumferential surface of the accommodating portion to press the signal pin into the accommodating portion.

In another general aspect, there is provided method of manufacturing a single-sided cooling power module, the method including preparing a direct bonded copper (DBC) substrate on which a pattern is formed to conduct electricity, installing a power device chip electrically connected to the pattern on the DBC substrate, coupling a power terminal to the DBC substrate, the power terminal being electrically connected to the pattern, installing a socket on a surface of the DBC substrate facing the power device chip, the socket being electrically connected to the pattern, forming a molding portion on the DBC substrate by placing the DBC substrate in an inner space surrounded by a lower molding die and an upper molding die and injecting a molding material into the inner space, separating the DBC substrate from the lower molding die and the upper molding die, and coupling a signal pin to the socket, the signal pin extending in a direction perpendicular to a surface of the DBC substrate, and the signal pin being electrically connected to the socket.

The installing of the socket may include bonding a bottom surface of a plate portion to the surface of the DBC substrate, forming an accommodating portion to extend from the plate portion in a direction perpendicular to the surface of the DBC substrate, and forming an accommodating hole in the accommodating portion, the accommodating hole being configured to receive the signal pin.

The method may include forming at least one protrusion on an inner circumferential surface of the accommodating portion to press the signal pin inserted into the accommodating portion.

One end of the socket may contact the upper molding die and the accommodating portion may be sealed by the upper molding die, in response to the DBC substrate being disposed in the inner space.

In another general aspect, there is provided method of manufacturing a single-sided cooling power module, the method including preparing a direct bonded copper (DBC) substrate on which a pattern is formed to conduct electricity, installing a power device chip electrically connected to the pattern on the DBC substrate, coupling a power terminal to the DBC substrate, the power terminal being electrically connected to the pattern, installing a socket on a surface of the DBC substrate facing the power device chip, the socket being electrically connected to the pattern, installing a guide pin having a columnar shape with a hollow in which an accommodating space is formed on the DBC substrate to accommodate the socket in the accommodating space, forming a molding portion on the DBC substrate by placing the DBC substrate in an inner space surrounded by a lower molding die and an upper molding die and injecting a molding material into the inner space, separating the DBC substrate from the lower molding die and the upper molding die, removing the guide pin from the DBC substrate, and coupling a signal pin to the socket, the signal pin extending in a direction perpendicular to a surface of the DBC substrate, and the signal pin being electrically connected to the socket.

The installing of the socket may include bonding a bottom surface of a plate portion to the surface of the DBC substrate, forming an accommodating portion to extend from the plate portion in a direction perpendicular to the one surface of the DBC substrate, and forming an accommodating hole in the accommodating portion, the accommodating hole being configured to receive the signal pin.

The method may include forming at least one protrusion on an inner circumferential surface of the accommodating portion to press the signal pin inserted into the accommodating portion.

One end of the guide pin may contact the upper molding die and the accommodating space is sealed by the upper molding die, in response to the DBC substrate being disposed in the inner space.

The guide pin may have a tip portion formed at the other end thereof, and the installing of the guide pin may include installing the guide pin on the DBC substrate such that at least a portion of the tip portion is inserted into the plate portion.

Other features and aspects will be apparent from the following detailed description, the drawings, and the claims.

### BRIEF DESCRIPTION OF THE DRAWINGS

FIG. 1 is a diagram illustrating a conventional single-sided cooling power module.

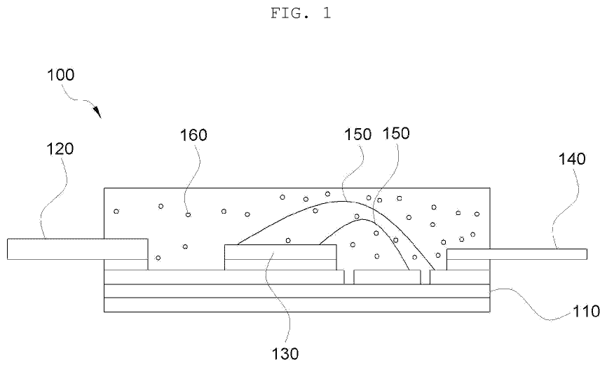

FIG. 2 is a diagram illustrating a single-sided cooling power module according to an embodiment.

FIG. 3 is a diagram illustrating a socket.

FIG. 4 is a flowchart illustrating a method of manufacturing a single-sided cooling power module according to a first embodiment.

FIG. 5 is a diagram illustrating a state in which when a direct bonded copper (DBC) substrate is disposed in an inner space surrounded by a lower molding die and an upper molding die, interference occurs between a signal pin and the upper molding die.

FIG. 6 is a diagram illustrating a state in which the DBC substrate on which the socket is installed is disposed in the inner space surrounded by the lower molding die and the upper molding die.

FIG. 7 is a diagram illustrating the DBC substrate on which a molding portion is formed.

FIG. 8 is a diagram illustrating a state in which a signal pin is coupled to the socket and installed on the DBC substrate.

FIG. 9 is a flowchart illustrating a method of manufacturing a single-sided cooling power module according to a second embodiment.

FIG. 10 is a diagram illustrating a guide pin coupled to the socket.

FIG. 11 is a diagram illustrating a state in which the DBC substrate on which the guide pin is installed is disposed in the inner space surrounded by the lower molding die and the upper molding die.

FIG. 12 is a diagram illustrating the DBC substrate from which the guide pin is removed after the molding portion is formed.

FIG. 13 is a diagram illustrating a state in which a signal pin is coupled to the socket and installed on the DBC substrate from which the guide pin is removed.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when it is said that a certain part is “connected” to another part, this not only means that they are “directly connected” to each other, but also means that they are “electrically connected” to each other with another member interposed therebetween.

Throughout the specification, when it is said that a certain member is positioned “on” another member, this not only means that they are in contact with each other, but also means that there is another member between the two members.

Also, throughout the specification, when it is said that a certain part “includes” a certain component, this means that the part may further include another component rather than excluding another component unless particularly specified otherwise. Throughout the specification, terms of approximation, such as “about” and “approximately”, are used to mean “equal to or close to” numerical values given for allowable manufacturing and material errors inherent in the stated meanings, and are used to prevent an unscrupulous infringer from unfairly using the disclosure where exact or absolute numerical values are stated to help understand the present invention. As used throughout the specification, the term “step of . . . ” does not mean “step for . . . ”

Hereinafter, an embodiments will be described in detail below with reference to the accompanying drawings. However, the present invention is not limited to the embodiments described herein, and may be embodied in other forms. Like reference signs denote like components throughout the specification.

Hereinafter, a single-sided cooling power module according to an embodiment of the present invention will be described.

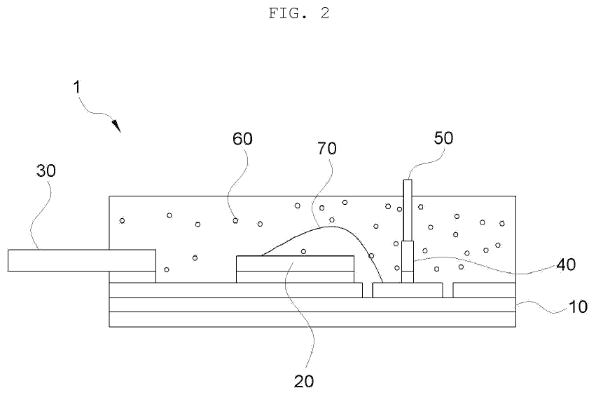

FIG. 2 is a diagram illustrating a single-sided cooling power module according to an embodiment.

Referring to FIG. 2, the single-sided cooling power module 1 includes a direct bonded copper (DBC) substrate 10, a power device chip 20, a power terminal 30, a socket 40, a signal pin 50, a molding portion 60, and a wire 70.

First, the DBC substrate 10 will be described.

The DBC substrate 10 may be formed by stacking at least one metal layer having good conductivity, such as copper, on an upper surface and a lower surface of a ceramic substrate.

A pattern capable of conducting electricity (hereinafter referred to as a pattern) may be formed on one surface of the DBC substrate 10.

Next, the power device chip 20 will be described.

The power device chip 20 may be formed in a structure in which a plurality of power devices are bonded in parallel to a metal wire formed on a predetermined substrate, and may be installed on one surface of the DBC substrate 10.

The power device chip 20 may be supplied with power from the power terminal 30, and may be formed of a conventional power device chip or the like capable of transmitting and receiving signals to and from the signal pin 50.

Next, the power terminal 30 will be described.

The power terminal 30 may be coupled to one surface of the DBC substrate 10 through soldering using solder, and may be electrically connected to at least a partial portion of the pattern formed on the DBC substrate 10.

Next, the socket 40 will be described.

The socket 40 may be installed on one surface of the DBC substrate 10 and electrically connected to at least a partial portion of the pattern.

In addition, the signal pin 50, which will be described later, may be coupled to the socket 40 to be electrically connected to the socket 40.

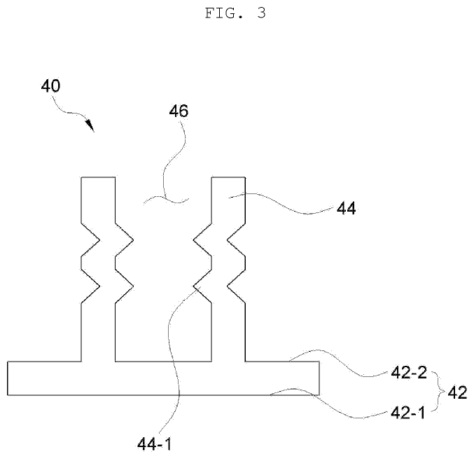

FIG. 3 is a diagram illustrating the socket.

Specifically, referring to FIG. 3, the socket 40 may include a plate portion 42 and an accommodating portion 44.

The plate portion 42 may include a bottom surface 42-1 bonded to one surface of the DBC substrate 10 and an ultrasonically bondable surface 42-2. Here, the bottom surface 42-1 may be formed to be flat so that the plate portion 42 is easily bonded to the DBC substrate 10 in a case where one surface of the DBC substrate 10 is flat.

The accommodating portion 44 may be formed to extend from the plate portion 42 in a direction perpendicular to one surface of the DBC substrate 10. An accommodating hole 46 allowing the signal pin 50 to be inserted thereinto may be formed in the accommodating portion 44.

In addition, at least one protrusion 44-1 capable of pressing the signal pin 50 inserted into the accommodating portion may be formed on an inner circumferential surface of the accommodating portion 44.

Next, the signal pin 50 will be described.

The signal pin 50 may be formed to extend in a longitudinal direction, installed on one surface of the DBC substrate 10 to extend in a direction perpendicular to one surface of the DBC substrate 10 facing the power device chip 20, and electrically connected to at least a partial portion of the pattern.

Specifically, the signal pin 50 may be installed in a direction perpendicular to one surface of the DBC substrate 10 by being inserted into the accommodating portion 44 of the socket 40, and the signal pin 50 inserted into the accommodating portion 44 may be coupled to the socket 40 by being pressed by the protrusion 44-1.

Next, the molding portion 60 will be described.

The molding portion 60 may be formed to bury components installed on the DBC substrate 10, including the power device chip 20.

The molding portion 60 may be formed of a polymer material having excellent insulating and protective properties, and may be formed of, for example, a material including an epoxy molding compound (EMC).

By forming the molding portion 60 as described above, the components buried in the molding portion 60, such as the power device chip 20, can be protected by the molding portion 60.

Next, the wire 70 will be described.

The wire 70 may be formed of a material capable of conducting electricity, and may be electrically connected to the power device chip 20 and electrically connected to the pattern, thereby electrically connecting the power device chip 20 and the signal pin 50 to each other.

Hereinafter, a method of manufacturing a single-sided cooling power module according to a first embodiment will be described.

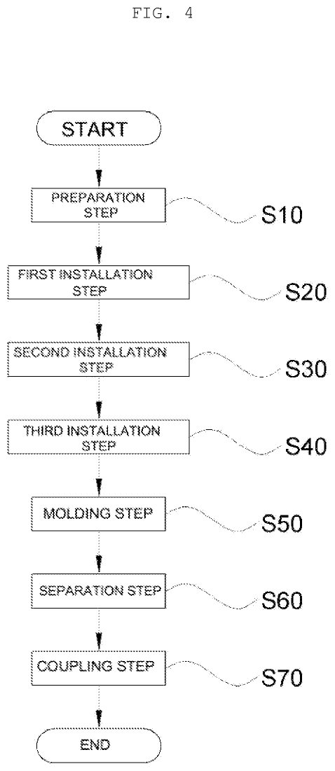

FIG. 4 is a flowchart illustrating the method of manufacturing a single-sided cooling power module according to the first embodiment.

Referring to FIG. 4, the method of manufacturing a single-sided cooling power module includes a preparation step S10, a first installation step S20, a second installation step S30, a third installation step S40, and a molding step S50, a separation step S60, and a coupling step S70.

First, the preparation step S10 will be described.

The preparation step S10 is a step of preparing a DBC substrate 10 on which a pattern capable of conducting electricity is formed.

The DBC substrate 10 may be formed by stacking at least one metal layer having good conductivity, such as copper, on an upper surface and a lower surface of a ceramic substrate.

A pattern capable of conducting electricity may be formed on one surface of the DBC substrate 10.

Next, the first installation step S20 will be described.

The first installation step S20 is a step of installing a power device chip 20 electrically connected to at least a partial portion of the pattern on the DBC substrate 10.

The power device chip 20 may be formed in a structure in which a plurality of power devices are bonded in parallel to a metal wire formed on a predetermined substrate, and may be installed on one surface of the DBC substrate 10.

The power device chip 20 may be supplied with power from the power terminal 30, and may be formed of a conventional power device chip or the like capable of transmitting and receiving signals to and from the signal pin 50.

Next, the second installation step S30 will be described.

The second installation step S30 is a step of coupling a power terminal 30 to the DBC substrate 10, the power terminal 30 being electrically connected to at least a partial portion of the pattern.

The power terminal 30 may be coupled to one surface of the DBC substrate 10 through soldering using solder, and may be electrically connected to at least a partial portion of the pattern formed on the DBC substrate 10.

Next, the third installation step S40 will be described.

The third installation step S40 is a step of installing a socket 40 electrically connected to at least a partial portion of the pattern on one surface of the DBC substrate 10 facing the power device chip 20.

The socket 40 may be installed on one surface of the DBC substrate 10 and electrically connected to at least a partial portion of the pattern.

In addition, the signal pin 50, which will be described later, may be coupled to the socket 40 to be electrically connected to the socket 40.

As illustrated in FIG. 3, the socket 40 may include a plate portion 42 and an accommodating portion 44.

The plate portion 42 may include a bottom surface 42-1 bonded to one surface of the DBC substrate 10 and an ultrasonically bondable surface 42-2. Here, the bottom surface 42-1 may be formed to be flat so that the plate portion 42 is easily bonded to the DBC substrate 10 in a case where one surface of the DBC substrate 10 is flat.

The accommodating portion 44 may be formed to extend from the plate portion 42 in a direction perpendicular to one surface of the DBC substrate 10. An accommodating hole 46 allowing the signal pin 50 to be inserted thereinto may be formed in the accommodating portion 44.

In addition, at least one protrusion 44-1 capable of pressing the signal pin 50 inserted into the accommodating portion may be formed on an inner circumferential surface of the accommodating portion 44.

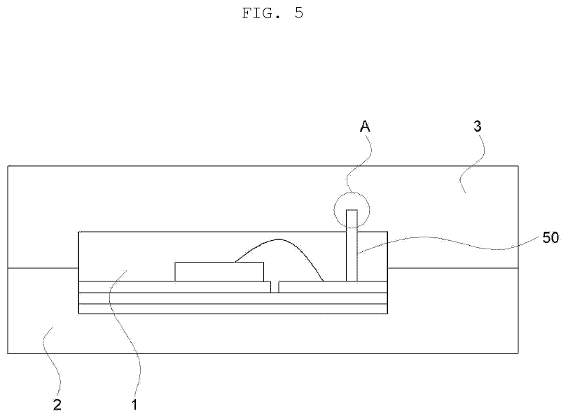

FIG. 5 is a diagram illustrating a state in which when a DBC substrate is disposed in an inner space surrounded by a lower molding die and an upper molding die, interference occurs between a signal pin and the upper molding die.

Referring to FIG. 5, when the DBC substrate 10 on which the signal pin 50 is installed is disposed in the inner space surrounded by the lower molding die 2 and the upper molding die 3, interference A may occur between the signal pin 50 and the upper molding die 3.

Therefore, by performing the molding step S50, which will be described later, after installing on the DBC substrate 10 the socket 40 to which the signal pin 50 can be coupled, and coupling the signal pin 50 to the DBC substrate 10 that has been subjected to the molding step S50, it is possible to prevent interference between the signal pin 50 and the upper molding die 3.

In order to prevent the molding material from flowing into the accommodating hole 46 during the molding step S50, the socket 40 may be formed in such a manner that, when the DBC substrate 10 is disposed in the inner space, one end of the socket 40 comes into contact with the upper molding die 3 and the accommodating portion 44 is sealed by the upper molding die 3.

Next, the molding step S50 will be described.

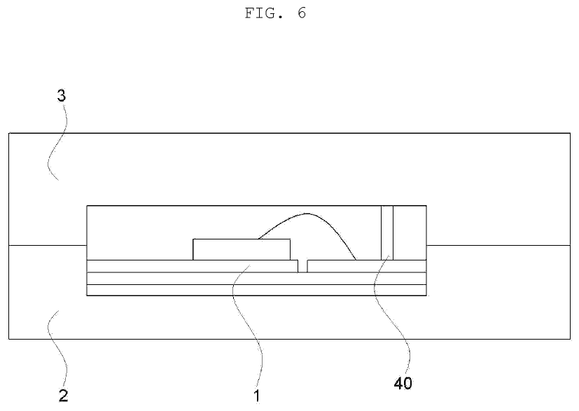

FIG. 6 is a diagram illustrating a state in which the DBC substrate on which the socket is installed is disposed in the inner space surrounded by the lower molding die and the upper molding die.

As illustrated in FIG. 6, the molding step S50 is a step of forming a molding portion 60 on the DBC substrate 10 by placing the DBC substrate 10 in an inner space surrounded by the lower molding die 2 and the upper molding die 3 and injecting a molding material into the inner space.

The molding portion 60 may be formed to bury components installed on the DBC substrate 10, including the power device chip 20.

The molding portion 60 may be formed of a polymer material having excellent insulating and protective properties, and may be formed of, for example, a material including an epoxy molding compound (EMC).

By forming the molding portion 60 as described above, the components buried in the molding portion 60, such as the power device chip 20, can be protected by the molding portion 60.

Next, the separation step S60 will be described.

The separation step S60 is a step of separating the DBC substrate 10 from the lower molding die 2 and the upper molding die 3.

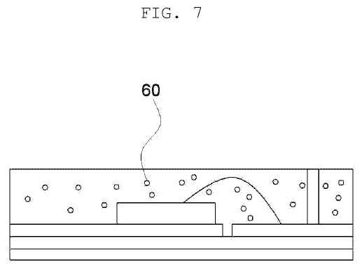

FIG. 7 is a diagram illustrating the DBC substrate on which the molding portion is formed.

Through the separation step S60, as illustrated in FIG. 7, the DBC substrate 10 separated from the lower molding die 2 and the upper molding die 3 with the molding portion 60 formed thereon can be manufactured.

Next, the coupling step S70 will be described.

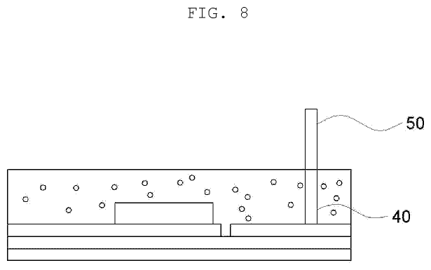

FIG. 8 is a diagram illustrating a state in which a signal pin is coupled to the socket and installed on the DBC substrate.

As shown in FIG. 8, the coupling step S70 is a step of coupling a signal pin 50 to the socket 40, the signal pin 50 being formed to extend in a longitudinal direction in such a manner as to be electrically connected to the socket 40 while extending in a direction perpendicular to one surface of the DBC substrate 10.

The signal pin 50 coupled to the socket 40 and installed on the DBC substrate 10 can be electrically connected to the DBC substrate, etc.

Hereinafter, a method of manufacturing a single-sided cooling power module according to a second embodiment will be described.

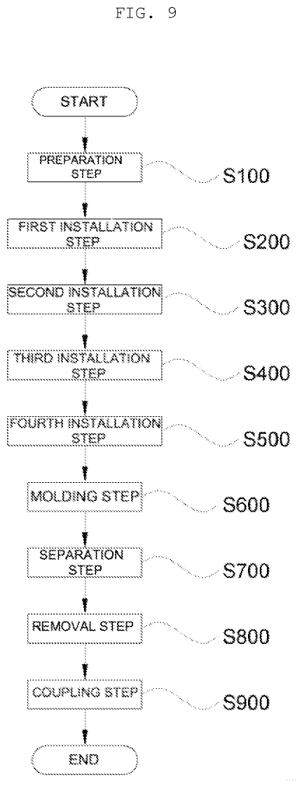

FIG. 9 is a flowchart illustrating the method of manufacturing a single-sided cooling power module according to the second embodiment.

Referring to FIG. 9, the method of manufacturing a single-sided cooling power module includes a preparation step S100, a first installation step S200, a second installation step S300, a third installation step S400, a fourth installation step S500, a molding step S600, a separation step S700, a removal step S800, and a coupling step S900.

First, the preparation step S100 will be described.

The preparation step S100 is a step of preparing a DBC substrate 10 on which a pattern capable of conducting electricity is formed.

The DBC substrate 10 may be formed by stacking at least one metal layer having good conductivity, such as copper, on an upper surface and a lower surface of a ceramic substrate.

A pattern capable of conducting electricity may be formed on one surface of the DBC substrate 10.

Next, the first installation step S200 will be described.

The first installation step S200 is a step of installing a power device chip 20 electrically connected to at least a partial portion of the pattern on the DBC substrate 10.

The power device chip 20 may be formed in a structure in which a plurality of power devices are bonded in parallel to a metal wire formed on a predetermined substrate, and may be installed on one surface of the DBC substrate 10.

The power device chip 20 may be supplied with power from the power terminal 30, and may be formed of a conventional power device chip or the like capable of transmitting and receiving signals to and from the signal pin 50.

Next, the second installation step S300 will be described.

The second installation step S300 is a step of coupling a power terminal 30 to the DBC substrate 10, the power terminal 30 being electrically connected to at least a partial portion of the pattern.

The power terminal 30 may be coupled to one surface of the DBC substrate 10 through soldering using solder, and may be electrically connected to at least a partial portion of the pattern formed on the DBC substrate 10.

Next, the third installation step S400 will be described.

The third installation step S400 is a step of installing a socket 40 electrically connected to at least a partial portion of the pattern on one surface of the DBC substrate 10 facing the power device chip 20.

The socket 40 may be installed on one surface of the DBC substrate 10 and electrically connected to at least a partial portion of the pattern.

In addition, the signal pin 50, which will be described later, may be coupled to the socket 40 to be electrically connected to the socket 40.

As illustrated in FIG. 3, the socket 40 may include a plate portion 42 and an accommodating portion 44.

The plate portion 42 may include a bottom surface 42-1 bonded to one surface of the DBC substrate 10 and an ultrasonically bondable surface 42-2. Here, the bottom surface 42-1 may be formed to be flat so that the plate portion 42 is easily bonded to the DBC substrate 10 in a case where one surface of the DBC substrate 10 is flat.

The accommodating portion 44 may be formed to extend from the plate portion 42 in a direction perpendicular to one surface of the DBC substrate 10. An accommodating hole 46 allowing the signal pin 50 to be inserted thereinto may be formed in the accommodating portion 44.

In addition, at least one protrusion 44-1 capable of pressing the signal pin 50 inserted into the accommodating portion may be formed on an inner circumferential surface of the accommodating portion 44.

Next, the fourth installation step S500 will be described.

The fourth installation step S500 is a step of installing a guide pin 80 having a columnar shape with a hollow in which an accommodating space is formed on the DBC substrate 10 in such a manner that the socket 40 is accommodated in the accommodating space.

In order to prevent the molding material from flowing into the accommodating space, the guide pin 80 may be formed in such a manner that, when the DBC substrate 10 is disposed in the inner space, one end of the guide pin 80 comes into contact with the upper molding die 3 and the accommodating space is sealed by the upper molding die 3.

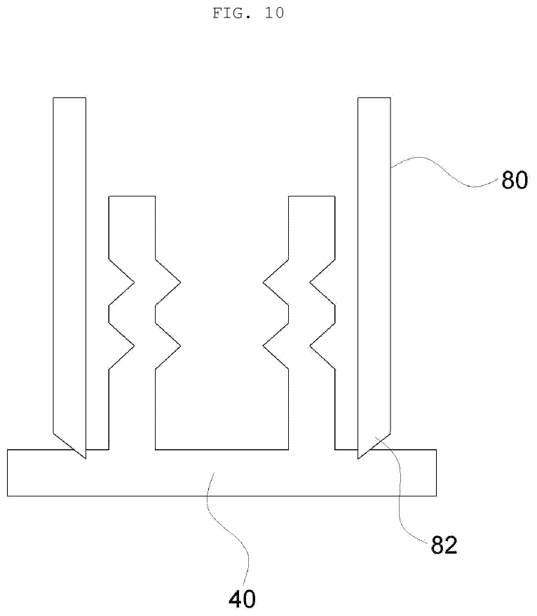

FIG. 10 is a diagram illustrating the guide pin coupled to the socket.

Meanwhile, as illustrated in FIG. 10, the guide pin 80 may have a tip portion 82 formed at the other end thereof, and the guide pin 80 may be installed on the DBC substrate 10 in such a manner that the guide pin 80 is pressed against the socket 40 to insert at least a partial portion of the tip portion 82 into the plate portion 42 of the socket 40.

Next, the molding step S600 will be described.

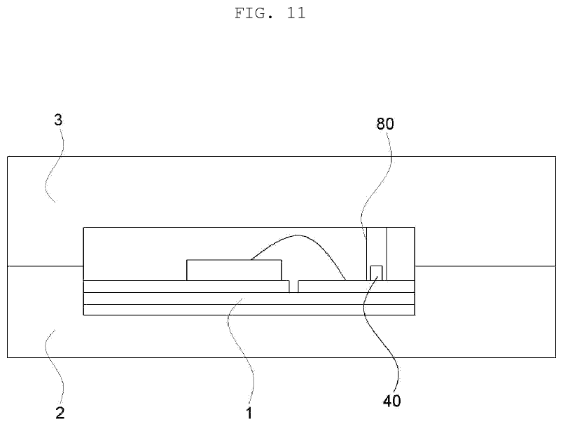

FIG. 11 is a diagram illustrating a state in which the DBC substrate on which the guide pin is installed is disposed in the inner space surrounded by the lower molding die and the upper molding die.

As illustrated in FIG. 11, the molding step S600 is a step of forming a molding portion 60 on the DBC substrate 10 by placing the DBC substrate 10 in an inner space surrounded by the lower molding die 2 and the upper molding die 3 and injecting a molding material into the inner space.

The molding portion 60 may be formed to bury components installed on the DBC substrate 10, including the power device chip 20.

The molding portion 60 may be formed of a polymer material having excellent insulating and protective properties, and may be formed of, for example, a material including an epoxy molding compound (EMC).

By forming the molding portion 60 as described above, the components buried in the molding portion 60, such as the power device chip 20, can be protected by the molding portion 60.

Next, the separation step S700 will be described.

The separation step S700 is a step of separating the DBC substrate 10 from the lower molding die 2 and the upper molding die 3.

Next, the removal step S800 will be described.

The removing step S800 is a step of removing the guide pin 80 from the DBC substrate 10.

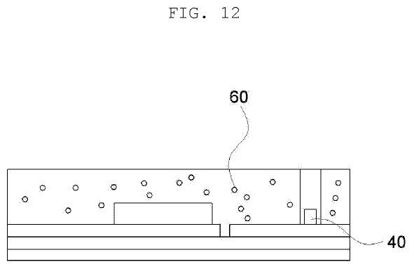

FIG. 12 is a diagram illustrating the DBC substrate from which the guide pin is removed after the molding portion is formed.

As illustrated in FIG. 12, through the separation step S700 and the removal step S800, it is possible to manufacture the DBC substrate 10 separated from the lower molding die 2 and the upper molding die 3, with the molding portion 60 formed on the DBC substrate 10, while the guide pin 80 is removed from the DBC substrate 10.

Next, the coupling step S900 will be described.

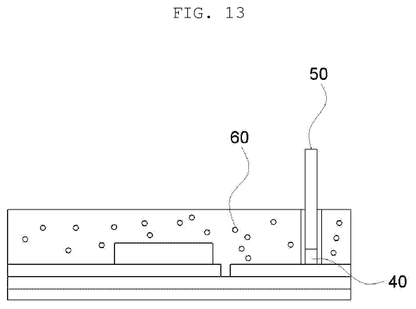

FIG. 13 is a diagram illustrating a state in which a signal pin is coupled to the socket and installed on the DBC substrate from which the guide pin is removed.

As illustrated in FIG. 13, the coupling step S900 is a step of coupling a signal pin 50 to the socket 40, the signal pin 50 being formed to extend in a longitudinal direction in such a manner as to be electrically connected to the socket 40 while extending in a direction perpendicular to one surface of the DBC substrate 10.

The signal pin 50 coupled to the socket 40 and installed on the DBC substrate 10 can be electrically connected to the DBC substrate, etc.

In the single-sided cooling power module and the method of manufacturing the same according to an embodiment, the signal pin is installed to extend in a direction perpendicular to one surface of the DBC substrate as described above. As a result, the single-sided cooling power module has a smaller volume.

In addition, since the distance between the power device chip and the signal pin is relatively close, inductance can be reduced.

An embodiment described-above is directed to providing a single-sided cooling power module having a smaller volume.

An embodiment described-above is directed to providing a single-sided cooling power module capable of reducing an inductance.

In the single-sided cooling power module and the method of manufacturing the same, the signal pin is installed to extend in a direction perpendicular to one surface of the DBC substrate. As a result, the single-sided cooling power module has a smaller volume.

In addition, since the distance between the power device chip and the signal pin is relatively close, inductance can be reduced.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

### REFERENCE NUMERALS

1: Single-sided cooling power module
10: DBC substrate
20: Power device chip
30: Power terminal
40: Socket
50: Signal pin
60: Molding portion
70: Wire
80: Guide pin

What is claimed is:

1. A single-sided cooling power module comprising:
a direct bonded copper (DBC) substrate on which a pattern is formed to conduct electricity;
a power device chip disposed on the DBC substrate and electrically connected to the pattern;
a power terminal coupled to the DBC substrate and electrically connected to the pattern; and
a signal pin extending in a direction perpendicular to a surface of the DBC substrate and facing the power device chip, the signal pin being electrically connected to the pattern.

2. The single-sided cooling power module of claim 1, further comprising a socket disposed on the surface of the DBC substrate and being electrically connected to the pattern,
wherein the signal pin is coupled to the socket and electrically connected to the socket.

3. The single-sided cooling power module of claim 2, wherein the socket comprises:
a plate portion comprising a bottom surface bonded to the surface of the DBC substrate and an ultrasonically bondable surface;
an accommodating portion extending from the plate portion in a direction perpendicular to the surface of the DBC substrate; and
an accommodating hole configured to receive the signal pin, the accommodating hole being formed in the accommodating portion.

4. The single-sided cooling power module of claim 3, wherein at least one protrusion is formed on an inner circumferential surface of the accommodating portion to press the signal pin into the accommodating portion.

5. A method of manufacturing a single-sided cooling power module, the method comprising:
preparing a direct bonded copper (DBC) substrate on which a pattern is formed to conduct electricity;
installing a power device chip electrically connected to the pattern on the DBC substrate;
coupling a power terminal to the DBC substrate, the power terminal being electrically connected to the pattern;
installing a socket on a surface of the DBC substrate facing the power device chip, the socket being electrically connected to the pattern;
forming a molding portion on the DBC substrate by placing the DBC substrate in an inner space surrounded by a lower molding die and an upper molding die and injecting a molding material into the inner space;
separating the DBC substrate from the lower molding die and the upper molding die; and
coupling a signal pin to the socket, the signal pin extending in a direction perpendicular to the DBC substrate, and the signal pin being electrically connected to the socket.

6. The method of claim 5, wherein the installing of the socket comprises:
bonding a bottom surface of a plate portion to the surface of the DBC substrate;
forming an accommodating portion to extend from the plate portion in a direction perpendicular to the surface of the DBC substrate; and
forming an accommodating hole in the accommodating portion, the accommodating hole being configured to receive the signal pin.

7. The method of claim 6, further comprising forming at least one protrusion on an inner circumferential surface of the accommodating portion to press the signal pin inserted into the accommodating portion.

8. The method of claim 7, wherein one end of the socket contacts the upper molding die and the accommodating portion is sealed by the upper molding die, in response to the DBC substrate being disposed in the inner space.

9. A method of manufacturing a single-sided cooling power module, the method comprising:
preparing a direct bonded copper (DBC) substrate on which a pattern is formed to conduct electricity;
installing a power device chip electrically connected to the pattern on the DBC substrate;
coupling a power terminal to the DBC substrate, the power terminal being electrically connected to the pattern;
installing a socket on a surface of the DBC substrate facing the power device chip, the socket being electrically connected to the pattern;
installing a guide pin having a columnar shape with a hollow in which an accommodating space is formed on the DBC substrate to accommodate the socket in the accommodating space;
forming a molding portion on the DBC substrate by placing the DBC substrate in an inner space surrounded by a lower molding die and an upper molding die and injecting a molding material into the inner space;
separating the DBC substrate from the lower molding die and the upper molding die;
removing the guide pin from the DBC substrate; and
coupling a signal pin to the socket, the signal pin extending in a direction perpendicular to a surface of the DBC substrate, and the signal pin being electrically connected to the socket.

10. The method of claim 9, wherein the installing of the socket comprises:
bonding a bottom surface of a plate portion to the surface of the DBC substrate;
forming an accommodating portion to extend from the plate portion in a direction perpendicular to the one surface of the DBC substrate; and
forming an accommodating hole in the accommodating portion, the accommodating hole being configured to receive the signal pin.

11. The method of claim 10, further comprising forming at least one protrusion on an inner circumferential surface of the accommodating portion to press the signal pin inserted into the accommodating portion.

12. The method of claim 11, wherein one end of the guide pin contacts the upper molding die and the accommodating space is sealed by the upper molding die, in response to the DBC substrate being disposed in the inner space.

13. The method of claim 12, wherein the guide pin has a tip portion formed at the other end thereof, and
the installing of the guide pin comprises installing the guide pin on the DBC substrate such that at least a portion of the tip portion is inserted into the plate portion.
